(19) United States
(12) Patent Application Publication
(10) Pub. No.: US 2003/0061558 A1
(43) Pub. Date: Mar. 27, 2003

(54) Double error correcting code system

(76) Inventors: Richard E. Fackenthal, Folsom, CA (US); Boubekeur Benhamida, Folsom, CA (US)

Correspondence Address: Timothy N. Trop, TROP, PRUNER & HU, P.C., STE 100, 8554 KATY FWY, HOUSTON, TX, 77024-1805, US

(21) Appl. No.: 09/962,828

(22) Filed: Sep. 25, 2001

(51) Int. Cl. H03M 13/00

(52) U.S. Cl. 714/755

(57) ABSTRACT

A data unit may be organized in error correcting rows and columns. Different error correcting algorithms may be utilized on the rows and columns. As a result, once a double error is identified in a given row, the location of each of the errors along the row may be determined using the column-wise error correcting algorithm. As a result, a single double error may be located and corrected after any other single errors have been corrected. In some embodiments, this may greatly increase the rate of successful error correction.

### BACKGROUND

This invention relates generally to processor-based systems and memories for processor-based systems, and particularly to systems for correcting data stored on those systems.

In electronic systems, data may be stored in memories. In some cases, in the course of storage or transport, the data may become corrupted. Thus, it is desirable to determine whether the data is corrupted, and even more desirable to correct the corrupted data, if possible. Error correcting codes have been developed that may accompany the stored data. Once the data is retrieved, a determination may be made about whether or not the retrieved data is correct. This determination is based on the accompanying error correcting codes. In some cases, if the stored information is incorrect, it may be corrected.

For example, one conventional error correcting code is known as the Hamming code. Standard Hamming codes are capable of correcting only a single error, and at most, detecting a double error. If a double error is detected, all that is known is that the data is corrupted, but nothing can conventionally be done to correct the errors without re-sending the data. As a result, the data must be re-sent, delaying the operation of the system and taxing its resources.

Simply re-sending the data does not correct the problem in the case of hard errors. Hard errors may arise when the data is programmed incorrectly, for example, due to noise. Thus, there is a need for forward error correcting systems that decrease the need to re-send data.

If the detected double errors could be corrected, at least in some cases, the frequency of re-sending the data may decreased, increasing the speed of the system and decreasing the load on the system resulting from double errors.

Thus, there is a need for ways to correct double errors in connection with error correcting codes.

### BRIEF DESCRIPTION OF THE DRAWINGS

FIG. 1 is a logical depiction of one embodiment of the present invention;

FIG. 2 is a flow chart in accordance with one embodiment of the present invention;

FIG. 3 is a flow chart in accordance with another embodiment of the present invention;

FIG. 4 is a flow chart for another embodiment of the present invention;

FIG. 5 is a continuation of the flow chart of FIG. 4;

FIG. 6 is a chart showing a comparison between the use of Hamming code alone and one embodiment of the present invention; and

FIG. 7 is a schematic depiction of one embodiment of the present invention.

### DETAILED DESCRIPTION

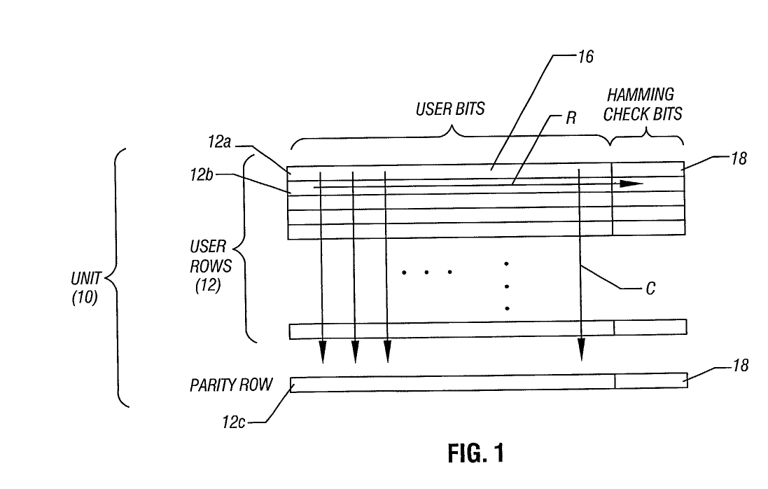

Referring to FIG. 1, a logical depiction of a unit 10 of data for error correction purposes includes rows 12 that extend in the horizontal direction (indicated by the letter R) and transverse columns (indicated by the arrows extending in the direction C). Thus, the unit 10 of data can be viewed as a two-dimensional data structure with error correcting rows 12 and error correcting columns. However, the terms “error correcting rows” and “error correcting columns” in this context are not logical rows or columns and do not necessarily have anything to do with physical rows and columns of conventional memory devices.

The unit 10 contains some number of rows 12 and columns. All rows 12, except the last row 12c, contain user data. Thus, the rows 12a and 12b are user rows and the row 12c may be a parity row in one embodiment. The parity row 12c contains parity data. Every row 12, including the user rows 12a and 12b and the parity row 12c, contains some number of user bits 16 and some number of Hamming check bits 18.

Of course, it should be appreciated that the depiction in FIG. 1 is purely a logical illustration and that these bits 16 and 18 may be stored in any physical manner on a memory medium. In addition, despite references being made to Hamming check bits 18 and a parity row 12c, other error correcting algorithms may be utilized in some embodiments of the present invention. Thus, Hamming check bits 18 may be utilized in rows 12 with another error correcting algorithm for the columns and a parity row may be utilized in some embodiments of the present invention with embodiments that do use an error correcting algorithm other than Hamming check bits. In still other embodiments, algorithms different from the Hamming and parity algorithms may be utilized.

State of the art Hamming schemes use some fixed amount of data to operate upon. Thus, in the illustrated embodiment, the Hamming code operates on the rows 12. The Hamming check bits 18 in each row 12 protect the user bits 16 in each row 12. Each row 12 represents a single error correcting, double error detecting scheme. The parity row 12c is treated just as the user rows 12a and 12b from the Hamming perspective. That is, the parity bits are also Hamming protected, as indicated at 18 in the parity row 12c, in accordance with one embodiment of the present invention.

Error correcting schemes are not perfect and some small fraction of errors will slip through any scheme, either detected, but not corrected, or undetected. If two errors appear on any row 12, the Hamming scheme for that row 12 detects the errors but can not correct them, without more information, because the scheme has no way of knowing where on the row 12 the two errors occurred. In other words the Hamming algorithm knows there are errors on the row but because it can not locate the errors it can not correct them.

Each bit in the parity row 12c is programmed so that the weight (i.e., the number of ones) of the column C is even or odd, as desired. Thus, each column C represents a parity scheme. With the help of the parity row 12c, a double error in an error correcting row 12 can be located and, therefore, may be fixed.

In one embodiment, all the single errors may be corrected so that if one double error remains, that double error can thereafter be corrected. Thus, in some embodiments, two passes may be utilized. In the first pass all the single errors are corrected and in the second pass, a single double error may be corrected. This offers a considerable advantage compared to existing schemes since the occurrence of a double error in conventional systems results in data corruption.

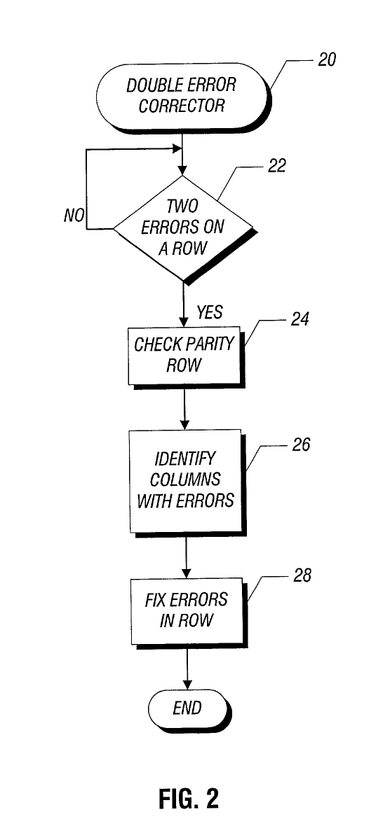

Referring to FIG. 2, the double error correcting algorithm 20 begins by determining whether there are two errors on any row, as indicated in diamond 22. If so, the parity row 12c may be checked, as indicated in block 24. Using the parity row 12c, the column with the errors is identified, as indicated in block 26. Then the errors, once their location is known, may be fixed, as indicated in block 28.

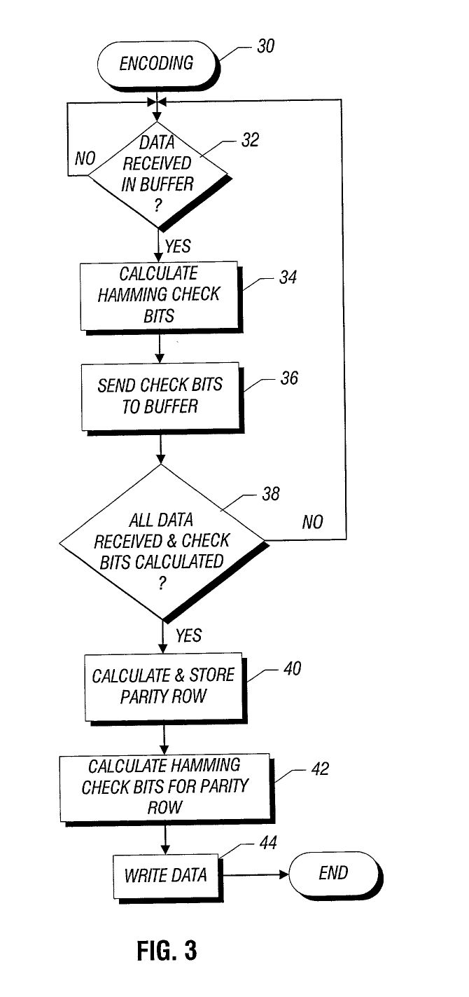

Referring to FIG. 3, the encoding algorithm 30 begins with data being received in a buffer, as determined in diamond 32. The data may arrive either serially or in parallel to a data buffer that is the size of one unit 10. When a row's worth of data is received, the Hamming check bits 18 are calculated and sent to the buffer, as indicated in block 34. When all user rows 12 have been received and the respective Hamming check bits 18 calculated, then the parity row 12c may be calculated and stored, as indicated in diamond 38 and in block 40. Finally, the Hamming check bits for the parity row 12c are calculated and stored in the buffer, as indicated in block 42.

The unit 10 of data is now ready to be written to the memory medium. For example, in the case of a flash memory, an on-board state machine may begin the algorithms involved in writing the unit 10 of data from the data buffer to the flash memory cells, as indicated in block 44.

In an alternative embodiment, the process of calculating the parity bits may occur simultaneously with receiving the row data and calculating the Hamming check bits. As a row 12 is received, the cumulative weight of each column may be tracked in a sequential circuit comprising a latch and feedback logic. In this way, the parity row 12c is ready to be written to the buffer immediately after the last user row 12 has been received and stored.

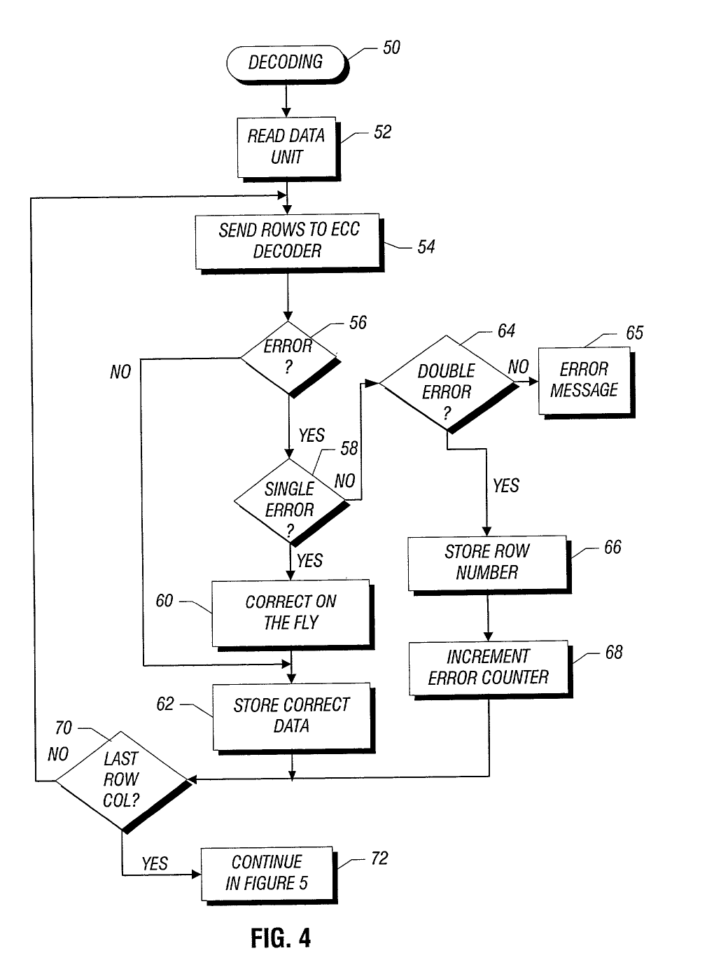

Referring to FIG. 4, the decoding algorithm 50 begins with the reading of a data unit 10 from the storage medium, such as a flash memory array, as indicated in block 52. Each row 12 is directed to an error correcting code (ECC) decoder for single error correction, as indicated in block 54. If an error is detected, as indicated in diamond 56, a check at diamond 58 determines whether or not the error is a single error. If so, the single error is corrected on the fly by the Hamming scheme for the row 12 that contains the error, as indicated in block 60. The corrected data may then be stored, as indicated in block 62.

If the error is not a single error, then the check at diamond 64 whether it is a double error. If so, the row number will be stored in a set of latches called the error address accumulator, as indicated in block 66 in one embodiment. An error counter is incremented, as indicated in block 68, in order to keep track of the number of rows that contain two errors, in one embodiment. If the error is not a single error and is not a double error, an error message may be generated, as indicated in block 65.

At the same time the decoding is taking place, the vertical parity of the unit 10 is calculated and accumulated. The last row 12 to be read is the parity row 12c that was stored earlier during the encoding phase. That parity row 12c is also Hamming corrected if needed, and its data is accumulated along with the other blocks to create the parity syndrome.

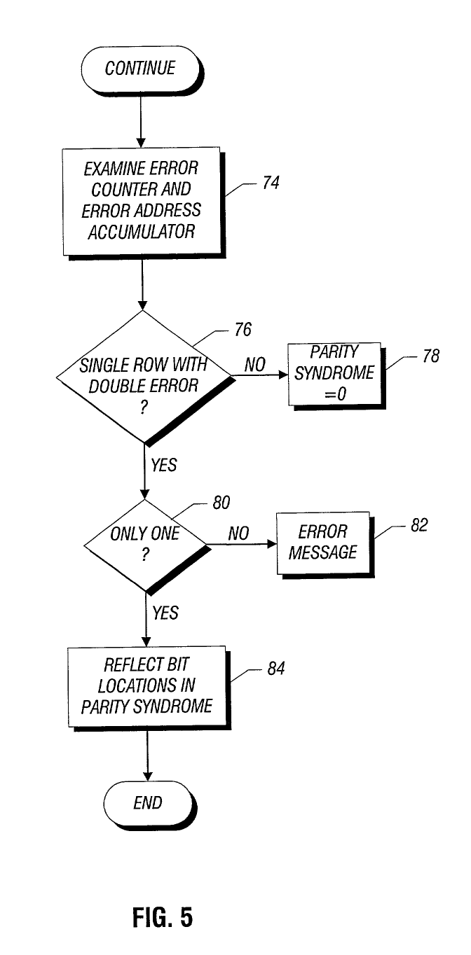

Thus, a check at diamond 70 determines whether or not the last row and column have been processed. If so, the flow continues to FIG. 5, as indicated in block 72.

Referring to FIG. 5, in block 74, a check is made of the error counter and address accumulator to determines if any single row contains a double error. In diamond 76, if there is no double error, the parity syndrome may be set equal to zero, as indicated in block 78. If one and only one row contains a double error, as determined in diamond 80, then the corresponding bit locations will be reflected in the parity syndrome, as indicated in block 84. Otherwise, an error message may be generated, as indicated in block 82. The scheme then knows which row contains a double error because the row number is stored in the error address accumulator. Thus, the parity syndrome and the error address accumulator allow the double error to be corrected as described previously.

With embodiments of the present invention, double errors may be corrected. Hamming schemes have a limited error correcting capability. However, the simplicity of Hamming correction systems in encoding and decoding makes them attractive for many applications. Hamming schemes are configurable to provide a wide variety of correcting capabilities, but with added capabilities come added cost, as measured in the number of extra check bits per a given number of user bits. In some embodiments of the present invention, the error correcting capability may be dramatically increased by providing the additional two error correction of one row in the unit 10 through the use of two-dimensions of error correction.

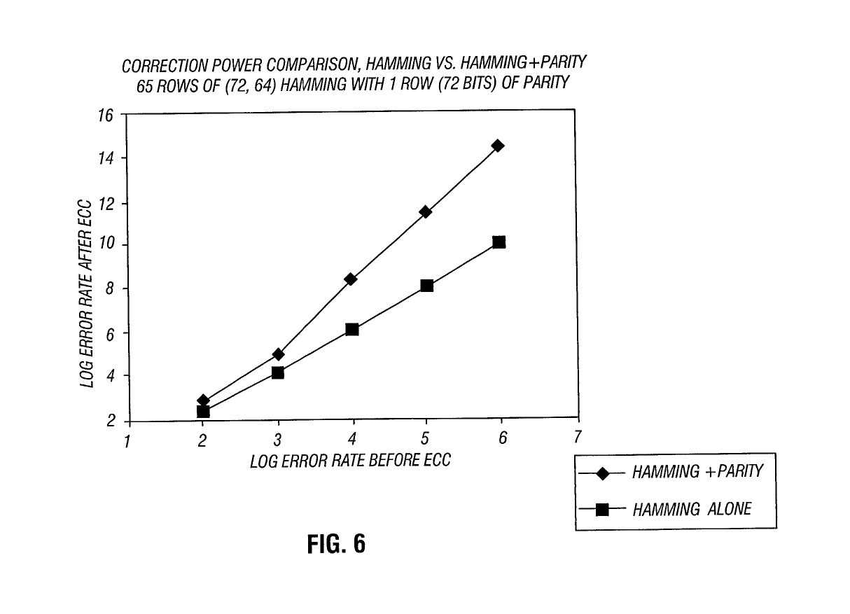

Thus, as shown in FIG. 6, the log error rate after ECC is significantly lower with the two-dimensional error correcting scheme. In the illustrated embodiment the unit 10 had sixty five rows 12 and one parity row 12c, each row included seventy-two bits 16 and 18. The log shows the after-ECC error rate (determined as one error in N bits, where N is the error rate) as a function of the before-ECC error rate, for a scheme using simple Hamming correction and an embodiment of the present invention. The steeper slope of the latter indicates a correcting power far greater than for Hamming alone, at similar costs. This is especially true as the before-ECC error rate increases, since the two lines diverge. At an input error rate of one in one million (six on the x-axis) an embodiment of the present invention may provide an output error rate four orders of magnitude better than with Hamming alone.

In some embodiments of the present invention, other error correcting schemes (such as Bose-Chaudhuri-Hocquenghem (BCH) codes) offer correction capabilities similar to the present scheme, at comparable cost. However, they are far more complex to decode, in some embodiments, requiring potentially tens of thousands of gates and other specialized devices and typically hundreds of processor cycles. In some embodiments of the present invention, a good compromise between low cost, complexity and correction capability has been achieved.

The present invention may be applied to a variety of memories including flash memories. In some embodiments, higher numbers of bits per cell may be utilized because of the increased error correction capability. For example, 4 bit per cell flash memories may be implemented with embodiments of the present invention.

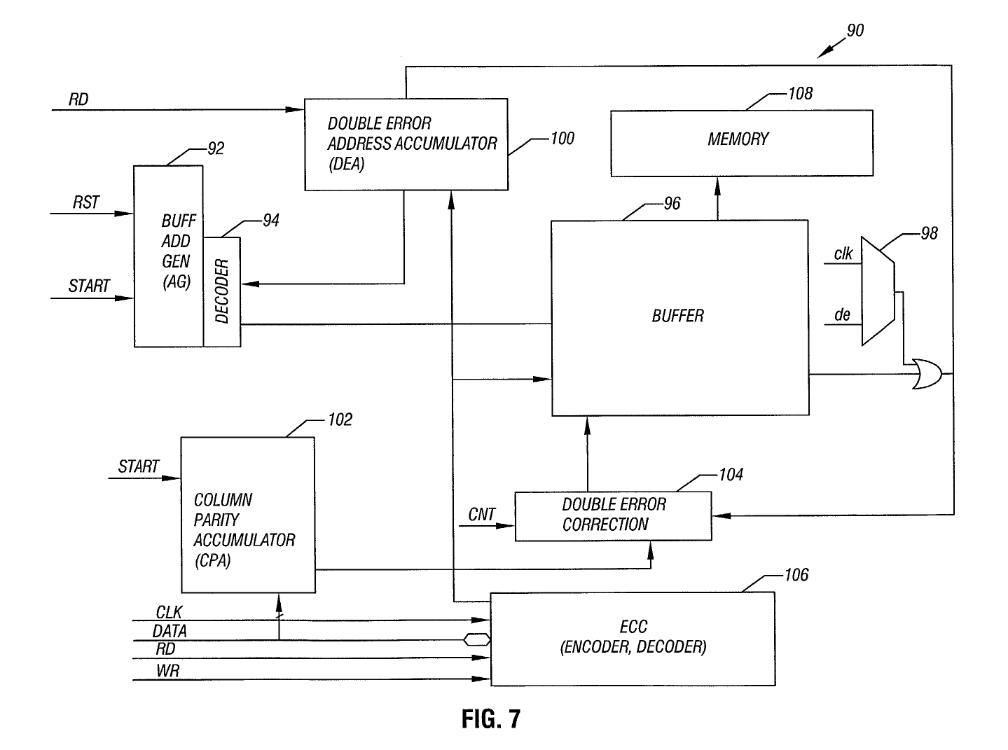

Referring finally to FIG. 7, a hardware architecture 90 in accordance with one embodiment of the present invention is illustrated. The buffer 96 is controlled by a buffer address generator 92 and decoder 94 that receives a reset (RST) signal and a start signal. A read (RD) signal is coupled to a double error address accumulator 100. The double error address accumulator 100 stores the addresses of any rows with double errors. A column parity accumulator 102 stores the column parity data for each column. A double error correction unit 104 implements the double error correction. The encoding and decoding may be done by an ECC encoder/decoder 106. The encoder/decoder 106 receives a clock signal (CLK), data, a read (RD) signal and a write (WR) signal. A double error counter 98 maintains the count of the number of double errors. When the single error and any double error have been corrected, the buffer 96 can forward the data for storage in a memory 108.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
arranging a data unit in error correcting rows and columns;
determining an error correction algorithm value for said rows and said columns; and
correcting a double error.

2. The method of claim 1 wherein determining an error algorithm value includes using different error correction algorithms for said rows and said columns.

3. The method of claim 2 including using a Hamming code on said rows and using a parity scheme on said columns.

4. The method of claim 1 including locating and correcting a single error, and then correcting a double error.

5. The method of claim 1 including providing an additional row of data for implementing an error correction algorithm on said columns.

6. The method of claim 5 including applying a first error correction algorithm on said rows and a second error correction algorithm on said columns, and providing said first error correction algorithm on said additional row.

7. The method of claim 6 including determining the error correction algorithm value for said rows and said columns one after the other.

8. The method of claim 6 including determining the error correction algorithm value for said rows and said columns in tandem.

9. The method of claim 1 including counting the number of double errors.

10. The method of claim 9 including determining whether the number of double errors exceeds a single double error.

11. An article comprising a medium storing instructions that enable a processor-based system to:
arrange a data unit in error correcting rows and columns;
determine an error correction algorithm value for said rows and said columns; and
correct a double error.

12. The article of claim 11 further storing instructions that enable a processor-based system to determine an error algorithm value for said rows and said columns.

13. The article of claim 12 further storing instructions that enable a processor-based system to use a Hamming code on said rows and use a parity scheme on said columns.

14. The article of claim 11 further storing instructions that enable a processor-based system to locate and correct a single error, and then correct a double error.

15. The article of claim 11 further storing instructions that enable a processor-based system to provide an additional row of data for implementing an error correction algorithm on said columns.

16. The article of claim 15 further storing instructions that enable a processor-based system to apply a first error correction algorithm on said rows and a second error correction algorithm on s aid columns, and provide said first error correction algorithm on said additional row.

17. The article of claim 16 further storing instructions that enable a processor-based system to determine the error correction algorithm value for said rows and said columns one after the other.

18. The article of claim 16 further storing instructions that enable a processor-based system to determine the error correction algorithm value for said rows and said columns in tandem.

19. The article of claim 11 further storing instructions that enable a processor-based system to count the number of double errors.

20. The article of claim 19 further storing instructions that enable a processor-based system to determine whether the number of double errors exceeds a single double error.

21. A system comprising:
a processor;
a storage coupled to said processor storing instructions that enable the processor to:
arrange a data unit in error correcting rows and columns;
determine an error correction algorithm value for said rows and said columns; and
correct a double error.

22. The system of claim 21 wherein said storage stores instructions that enable the processor to determine an error algorithm value for said rows and said columns.

23. The system of claim 22 wherein said storage stores instructions that enable the processor to use a Hamming code on said rows and use a parity scheme on said columns.

24. The system of claim 21 wherein said storage stores instructions that enable the processor to locate and correct a single error, and then correct a double error.

25. The system of claim 21 wherein said storage stores instructions that enable the processor to provide an additional row of data for implementing an error correction algorithm on said columns.

26. The system of claim 25 wherein said storage stores instructions that enable the processor to apply a first error correction algorithm on said rows and a second error correction algorithm on said columns, and provide said first error correction algorithm on said additional row.

27. The system of claim 26 wherein said storage stores instructions that enable the processor to determine the error correction algorithm value for said rows and said columns one after the other.

28. The system of claim 26 wherein said storage stores instructions that enable the processor to determine the error correction algorithm value for said rows and said columns in tandem.

29. The system of claim 21 wherein said storage stores instructions that enable the processor to count the number of double errors.

30. The system of claim 29 wherein said storage stores instructions that enable the processor to determine whether the number of double errors exceeds a single double error.
